(19) United States
(12) Patent Application Publication
(10) Pub. No.: US 2026/0144064 A1
(43) Pub. Date: May 21, 2026

(54) SYSTEMS AND METHODS FOR SEMICONDUCTOR WAFER-LEVEL PACKAGING

(71) Applicant: Samsung Electronics Co., Ltd., Suwon-si (KR)

(72) Inventors: Yan LI, Morgan Hill, CA (US); WooPoung KIM, San Jose, CA (US)

(21) Appl. No.: 19/060,629

(22) Filed: Feb. 21, 2025

Related U.S. Application Data
(60) Provisional application No. 63/722,581, filed on Nov. 19, 2024.

(51) Int. Cl. H01L 23/473; H01L 23/00; H01L 23/538; H01L 25/18; H10D 1/68

(52) U.S. Cl. CPC H10W 40/47; H10W 70/611; H10W 90/00; H10W 90/401; H10D 1/68; H10W 72/073; H10W 90/734

(57) ABSTRACT

A system and a method for an integrated semiconductor wafer are disclosed. A wafer-level interposer has a top interposer surface and a bottom interposer surface. A power layer is disposed on the top interposer surface. The power layer includes at least one voltage regulator module (VRM). A first layer is attached to the bottom interposer surface. The first layer includes at least one first-layer die having at least one first-layer integrated circuit (IC). A second layer is attached to the first layer. The second layer includes at least one second-layer die having at least one second-layer IC. A wafer-level thermal layer has an embedded cooling network of at least one liquid cooling channel and is attached to the second layer.

### CROSS-REFERENCE TO RELATED APPLICATION

This application claims the priority benefit under 35 U.S.C. § 119(e) of U.S. Provisional Patent Application Ser. No. 63/722,581 filed on Nov. 19, 2024, the disclosure of which is incorporated by reference in its entirety as if fully set forth herein.

### TECHNICAL FIELD

The disclosure generally relates to semiconductor packaging. More particularly, the subject matter disclosed herein relates to semiconductor wafer-level packaging.

### BACKGROUND

The present background section is intended to provide context only, and the disclosure of any concept in this section does not constitute an admission that said concept is prior art.

Demands in high performance computing in mobile communication, artificial intelligence (AI), machine learning (ML), and media computing have created many requirements in semiconductor technology. These requirements include large storage capacity, low power consumption, small footprints, and fast accesses to caches, static random-access memory (SRAM), dynamic random-access memory (DRAM), and high-bandwidth memory (HBM) devices.

Designing systems that utilize these components faces several challenges. Placement of heterogeneous components on a small platform requires a complex and delicate balance between power consumption, signal integrity, and propagation delays. Suppressing heat dissipation among components often creates unsatisfactory thermal management or bottlenecks in interconnections.

The above information disclosed in this Background section is only for enhancement of understanding of the background of the disclosure and therefore it may contain information that does not constitute prior art.

### SUMMARY

To overcome these issues, systems and methods are described herein for a technique of fabricating highly integrated semiconductor wafer that combines heterogenous components such as applications specific integrated circuits (ASICs), memories, input/output (IO) circuits, and interface circuits in a single wafer. The technique employs a systematic integrating approach to achieve many objectives for structural coherence including gapless three-dimensional (3D) integration of heterogeneous components, flexibility in component placement, reduced interconnection distances using gapless die stacking, improved thermal management with diamond or silicon (Si)/glass wafers having embedded cooling channels, and improved power delivery performance with glass or Si substrate having embedded decoupling capacitors and integration of integrated stack capacitors, backside power delivery network, voltage regulator modules in circuits. In addition, the fabrication process is efficient and does not involve molding compound material and grinding process which may cause thermal and mechanical concerns.

In an embodiment, a semiconductor integrated wafer or wafer-level circuit packs multiple dies or chips in a single wafer. The highly dense device offers several advantages over other packaging solutions. These include enhanced performance, power and space efficiency, and improved reliability and testing. The integrated wafer includes at least a wafer-level interposer, a power layer, a first layer, a second layer, and a wafer-level thermal layer. The wafer-level interposer has a top interposer surface and a bottom interposer surface. The power layer is disposed on the top interposer surface and includes M, where M is a positive integer, voltage regulator modules (VRMs). The first layer is attached to the bottom interposer surface. The first layer includes N, where N is a positive integer, first-layer dies having first-layer integrated circuits (ICs). The second layer is attached to the first layer. The second layer includes P, where P is a positive integer, second-layer dies having second-layer ICs. The wafer-level thermal layer has an embedded cooling network of liquid cooling channels and is attached to the second layer.

### BRIEF DESCRIPTION OF THE DRAWINGS

In the following section, the aspects of the subject matter disclosed herein will be described with reference to exemplary embodiments illustrated in the figures, in which:

FIG. 1 is a block diagram illustrating a system that utilizes a wafer-level circuit in an artificial intelligence (AI) application according to an embodiment.

FIG. 2 is a diagram illustrating an integrated wafer-level circuit that represents a wafer-level packaging according to an embodiment.

FIG. 3 is a diagram illustrating a section of the integrated wafer-level circuit that shows adjacent dies according to an embodiment.

FIG. 4 is a diagram illustrating the first four stages of the manufacturing process of the integrated wafer-level circuit according to an embodiment.

FIG. 5 is a diagram illustrating the second four stages of the manufacturing process of the integrated wafer-level circuit according to an embodiment.

FIG. 6 is a diagram illustrating the last three stages of the manufacturing process of the integrated wafer-level circuit according to an embodiment.

FIG. 7 is a diagram illustrating an integrated wafer-level circuit having ASICs with and without backside power delivery network (BSPDN) according to an embodiment.

FIG. 8 is a diagram illustrating an integrated wafer-level circuit having a mix of ICs in the layers according to an embodiment.

FIG. 9 is a diagram illustrating an integrated wafer-level circuit having a mix of memory stacks in the layers according to an embodiment.

FIG. 10 is a diagram illustrating an integrated wafer-level circuit having the layer circuits re-arranged in the layers according to an embodiment.

FIG. 11 is a diagram illustrating an integrated wafer-level circuit having a heat sink or lid according to an embodiment.

FIG. 12 is a flow chart illustrating a process of manufacturing an integrated wafer-level circuit according to an embodiment.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “module” refers to any combination of software, firmware and/or hardware configured to provide the functionality described herein in connection with a module. For example, software may be embodied as a software package, code and/or instruction set or instructions, and the term “hardware,” as used in any implementation described herein, may include, for example, singly or in any combination, an assembly, hardwired circuitry, programmable circuitry, state machine circuitry, and/or firmware that stores instructions executed by programmable circuitry. The modules may, collectively or individually, be embodied as circuitry that forms part of a larger system, for example, but not limited to, an integrated circuit (IC), system on-a-chip (SoC), an assembly, and so forth.

Many applications, especially applications in Artificial Intelligence (AI) and signal processing, require a vast storage capacity and high throughput computations. To satisfy these needs, highly dense circuits would be packed into highly integrated packages with very short interconnection delays. In addition, for high-speed applications, decoupling capacitors would need to be placed at strategic locations to maintain signal integrity without occupying much space. In the following, systems and methods are described for a technique of fabricating highly integrated semiconductor wafer-level packages that combine heterogenous digital components (e.g., applications specific integrated circuits (ASICs), memories, and input/output (IO) or interface circuits) with other passive or mechanical elements to provide fast processing time in a noise-suppressing and well-managed thermal environment.

In one embodiment, a system and a method for a semiconductor wafer-level package that integrates several types of circuits for performance improvement are disclosed. By integrating several types of circuits into a single wafer, the wafer-level package reduces latency, increases bandwidth, and improves signal integrity. The packaging is highly space efficient because it is generated using wafer-level bonding techniques such as die-to-wafer and/or wafer-to-wafer. A wafer-level interposer has a top interposer surface and a bottom interposer surface. A power layer is disposed on the top interposer surface. The power layer includes at least one voltage regulator module (VRM) to deliver and distribute stable voltages to various components in the circuit. A first layer is attached to the bottom interposer surface. The first layer has a top first surface and a bottom first surface and includes at least one first-layer die having at least one first-layer integrated circuit (IC). A second layer is attached to, or bonded on, the first layer. The second layer has a top second surface and a bottom second surface and includes at least one second-layer die having at least one second-layer IC. These layers are attached together using die-on-wafer bonding which minimizes component distances and reduces energy waste. A wafer-level thermal layer has an embedded cooling network of at least one liquid cooling channel and is attached to the second layer using wafer-on-wafer fusion bonding. The thermal layer may be made of diamond, silicon, or glass to provide efficient thermal management.

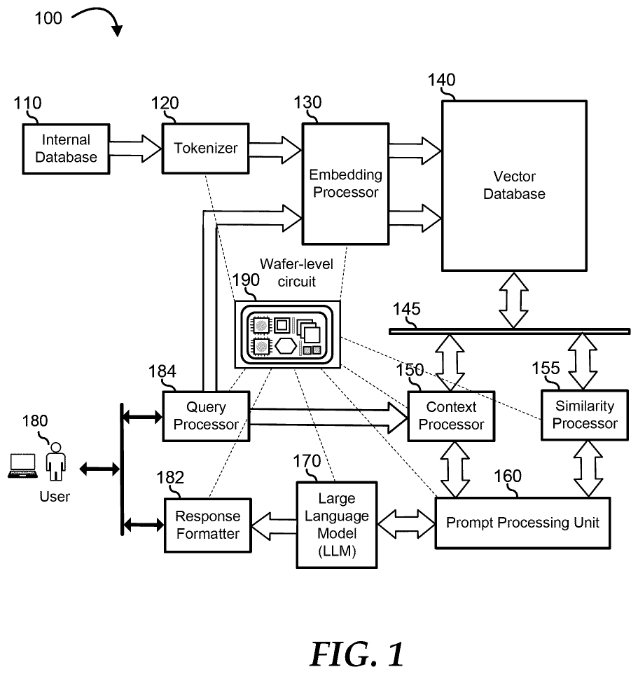

FIG. 1 is a block diagram illustrating a system 100 according to an embodiment. The system 100 includes an internal database 110, a tokenizer 120, an embedding processor 130, a vector database 140, a connectivity link 145, a context processor 150, a similarity processor 155, a prompt processing unit 160, a large language model (LLM) 170, a response formatter 182, a query processor 184, a user 180, and an integrated wafer or wafer-level circuit or package 190. The system 100 may include more or less than the above components. The system 100 illustrates an exemplary architecture of an artificial intelligence (AI) query-and-response application. This query-and-response application receives queries from the user 180 and provide the response using the LLM 170. This type of application may be implemented by hardware or software or a combination of both. The reason why this application is used as an example to illustrate the role of the highly integrated system on wafer (SoW) is that it uses very large computational resources including large storages for data and high computations. Whether it is implemented by hardware, software, or a combination of both, the basic component of the system is an integrated wafer 190 that may perform all or parts of the functions of the tokenizer 120, the embedding processor 130, the context processor 150, the similarity processor 155, the prompt processing unit 160, the LLM 170, the response formatter 182, and the query processor 184. Some of the components may be parts of other components. For example, the tokenizer 120 and the embedding processor 130 may be parts of the LLM 170.

The internal database 110 is a database that stores data or information that is private to an organization and is not available publicly. The query session may be used by an employee of a company and therefore the data may be private or proprietary to the company. The internal database 110 may not be needed if the query is for public information. The tokenizer 120 processes the data from the internal database 110 and prepares for use in subsequent stages. A typical input is a text or a sentence. The tokenizer 120 breaks the text into smaller units, called tokens, which may be a word or a phrase, or a form that can be processed by other units. Typically, this task may include extracting relevant information from the text and represent this information by meaningful numbers. This may be performed by a special program, or a special circuit which may be implemented in an applications-specific integrated circuit (ASIC). Such an ASIC would need to have fast access to memories which store the texts and the tokens. An ASIC with direct access to a storage element in the same package is useful for this purpose.

The embedding processor 130 operates on the output of the tokenizer and the query processor to convert this textual representation into a numeric representation that follows some predefined format. The embedded representation typically has several fields of numbers which may correspond to relevance, relationship, or any characteristics that are useful for processing. These embedded representations typically form vectors. For example, the textual representation “I love New York” may be embedded into a vector having five fields: [0.312, −7.215, 3.126, −0.015, 2.761]. The embedding process may be implemented in hardware using an integrated wafer 190 including an ASIC that calculates the vector representation and storage elements that store information retrieved from the internal database 110. The resulting vectors may be stored in the vector database 140 or may be processed with data read from the vector database 140. The vector database 140 store vectors that represent domain knowledge and/or the query. The output of the vector database 140 may be passed to the context processor 150 and the similarity processor 155 via the connectivity link 145 for further processing. The connectivity link 145 may be a bus, a network connection, or any medium that allows ata transfers between the vector database 140 and other devices including the context processor 150 and the similarity processor 155

The context processor 150 provides contextual information to the query or queries. It receives query information from the query processor 184. The contextual information expands the meaning of the query or queries to include information that is relevant to the content of the query or queries and/or user's background and experience. For example, the queries “What is the capital of California?” “What to do in Central California?” and “Where is Yosemite?” may create a context of traveling. This context will obtain vectors that are related to traveling in California including lodging information and attractions. The context processor 150 therefore requires fast computation to perform searches and matching. It also needs a large memory space to store data. The similarity processor 155 performs matching of candidate vectors to the query vector or vectors to locate the vectors that are most relevant to the query. Depending on the format of the query, an appropriate similarity measure may be determined. For example, for vectors with many numerical values, a cosine similarity may be used. This similarity measure requires calculating an inner product and magnitudes of two vectors. When searching for relevant vectors, thousands of such computations may be performed. This number of computations necessitates an ASIC dedicated for similarity computations. Accordingly, the similarity processor 155 may be efficiently implemented by multiple highly integrated packages that include computational elements in forms of ASIC chiplets for fast and parallel computations. In addition, it should also have a large memory capacity to provide fast access to the vectors. Both the context processor 150 and the similarity processor 155 would also need efficient input/output (IO) circuits to perform fast data transfers to and from the vector database 140 and the prompt processing unit 160.

The prompt processing unit 160 receives results from the context processor 150 and the similarity processor 155 to further provide guidance to steer the LLM 170 to the appropriate direction. Due to the amount of vast information processed by the LLM 170, there is a good chance that the LLM 170 strays into off topic areas, referred to as hallucinations. The prompt processing unit 160 narrows down the search space, based on the contextual information from the context processor 150 and the candidate vectors from the similarity processor 155 and additional information such as user's profile, background, or experience. The prompt processing unit 160 may import domain-specific knowledge data to generate proper directions for the query. It may interact with the context processor 150 and the similarity processor 155 in generate prompts to the LLM 170. Accordingly, it would need a highly integrated package or an SoW with ASIC chiplets and localized memory and IO or interface circuits.

The LLM 170 obtains results from the prompt processing unit 160 including those of the context processor 150 and the similarity processor 155 to generate a response to the query. It also receives query information from the query processor 184. The LLM 170 includes a transformer model having computations that are partly offloaded to the tokenizer 120, the embedding processor 130, the context processor 150, and the similarity processor 155. It includes an encoder and decoder structure to create and process a contextualized representation of the query, a training model to learn the meaning of the query and process the query, an inference engine to reason for a proper response, and a fine-tuning structure to refine the responses based on the results of the context processor 150 and the similarity processor 155. Typically, the LLM 170 involves a massive amount of memory space and computations. Many of the computations may be performed in parallel where there is little or no dependency. Accordingly, the LLM 170 would need multiple highly integrated packages having several computational and memory elements with specific algorithms. This is most efficient by multiple ASICs with direct accesses to local memory devices.

The response formatter 182 receives one or more responses from the LLM 170. These responses correspond to the user query or queries. The response formatter 182 formats these responses in proper format and presentation style which may include graphics and animation. The result is then delivered to the user 180. Due to the amount of computations and IO interactions, the response formatter 182 is best implemented by a highly integrated package like the integrated wafer, wafer package, or wafer-level package 190 which includes multiple ASIC, memory, and IO circuits.

The query processor 184 processes the query from the user 180. This process may include tokenization as done by the tokenizer 120 and other formatting operations to convert the user's query into a form that can be further processed. The results of the query processor 184 are delivered to the embedding processor 130, the context processor 150, and the LLM 170. Though the computations in the query processor 184 may or may not be extensive, it often needs fast processing time and specialized procedures. Accordingly, the query processor 184 is best implemented by a highly integrated package having multiple ASIC, memory, and IO circuits.

The user 180 may be any user of the system and may include an individual, a team of people, or a computerized process. The user 180 may have a query that is in the public domain an expect the results to be obtained from the public domain. The user 180 may also be a user who has a private query that is particularized for the platform the user 180 is using. For example, the user 180 may be an individual who is interested in knowing the products offered by a company XYZ. As another example, the user 180 may belong to an organization such as a union or an association who want to query a particular subject that is relevant only to that organization. Under this private setting, the internal database 110 is relevant.

The wafer-level circuit, wafer package, or wafer-level package 190 provides highly integrated resources for the various components in the system 100. These resources may include computations, storage, processing operations, and other specialized functions. The wafer-level circuit or package 190 may be used in any one of the tokenizer 120, the embedding processor 130, the context processor 150, the similarity processor 155, the prompt processing unit 160, the LLM 170, the resource formatter 182, or the query processor 184, or any combination of these elements,

The system 100 is an example that illustrates the role of highly integrated packages or wafer-level circuits in high computing (HC) platforms. The use of a query application in AI shows that many HC platforms require several ASIC chiplets operating in conjunction with memory or IO circuits. In many cases, the environment of the applications adds additional requirements including low power consumption, reliable signal integrity, fault-tolerance, and reliable operations in extreme conditions including heat and tight space. Examples of other applications that would benefit from a highly integrated wafer design include mobile communication (e.g., smart phones, base stations, user equipment), cameras, vehicles, entertainment (e.g., games, multimedia, music, movies), technical designs (e.g., animation, graphics), medical (e.g., visualization, medical imaging), robotics, drones, automatic test equipment, audio processing, speech synthesizer, video and image analysis, vision, automatic face recognition, artificial intelligence (AI) applications, and data centers. Many of these requirements present challenges because they may lead to contradictory requirements. Accordingly, embodiments described in this disclosure aim at achieving these objectives with a systematic approach for structural and operational coherence. Structural coherence refers to consistency in placement of components to achieve various objectives. For example, when more components are packed together such as stacked memory circuits, a cooling channel would be placed near these components. As another example, when high-frequency operations are performed, stacked capacitors would be placed nearby to maintain signal integrity and reduce noise. In addition to structural and operational coherence, embodiments offer an architecture that provides flexibility and scalability so that the integrated wafer may be modified to accommodate different environments or applications.

In the following, the description will focus on several embodiments of the integrated wafer or wafer-level circuit or package 190. These embodiments may be combined to provide highly integrated and versatile packages or wafers.

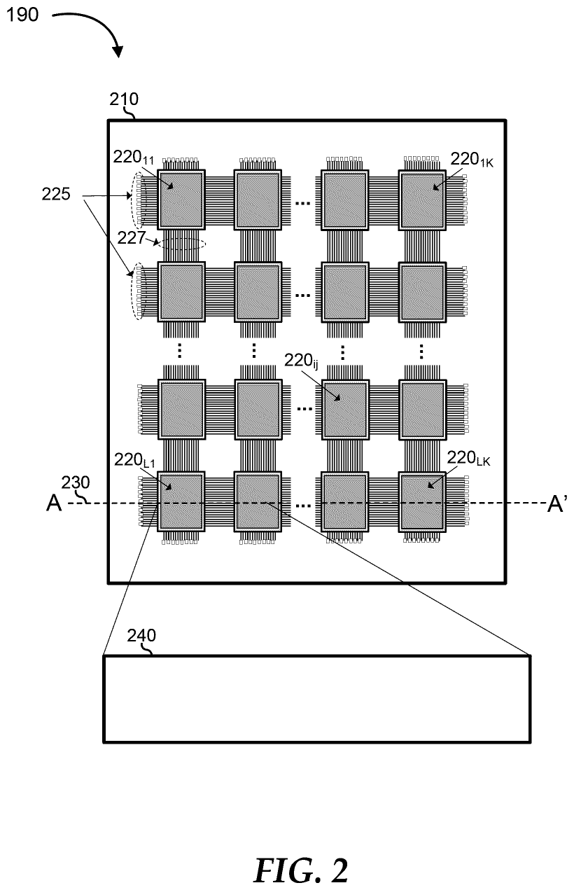

FIG. 2 is a diagram illustrating the integrated wafer-level circuit or package 190 shown in FIG. 1 according to an embodiment. The term “wafer-level” refers to the process steps taking place at the wafer level, meaning the entire wafer, instead of at the die level. The integrated wafer-level circuit or package 190 integrates several functional dies or circuits such as processors, memories, and specialized processing elements (e.g., graphics, imaging, audio, accelerators, text processing, floating-point processing) onto a single large-scale wafer to create a structurally and functionally coherent system. By integrating components directly on the wafer, the integrated wafer-level circuit 190 achieves higher performance, lower power consumption, and improved efficiency compared to traditional chip-based systems. The advantages of the integrated wafer-level circuit 190 include reduced interconnect delay, heterogeneous integration, power efficiency, thermal management efficiency, and high signal integrity.

The placement of the circuits or dies in the integrated wafer-level circuit 190 may follow any convenient or technologically advantageous arrangement. In one embodiment, the placement of the circuits is arranged in a rectangular area having rows and columns. Seen from the top, the integrated wafer-level circuit 190 has an area or region 210. The region 210 includes circuits 220ᵢⱼ's where i=1, . . . , L and j=1, . . . , K. The circuits 220ᵢⱼ's may be homogeneous (i.e., having the same type) or heterogeneous (i.e., having different types) and may have the same or different dimensions. The circuits 220ᵢⱼ's are interconnected together by horizontal interconnecting wires or traces 225 and vertical interconnecting wires or traces 227. A sectional view 240 may be obtained at the cross-sectional line 230. For simplicity, the cross-sectional view 240 is obtained for two horizontally adjacent circuits 220ᵢⱼ's.

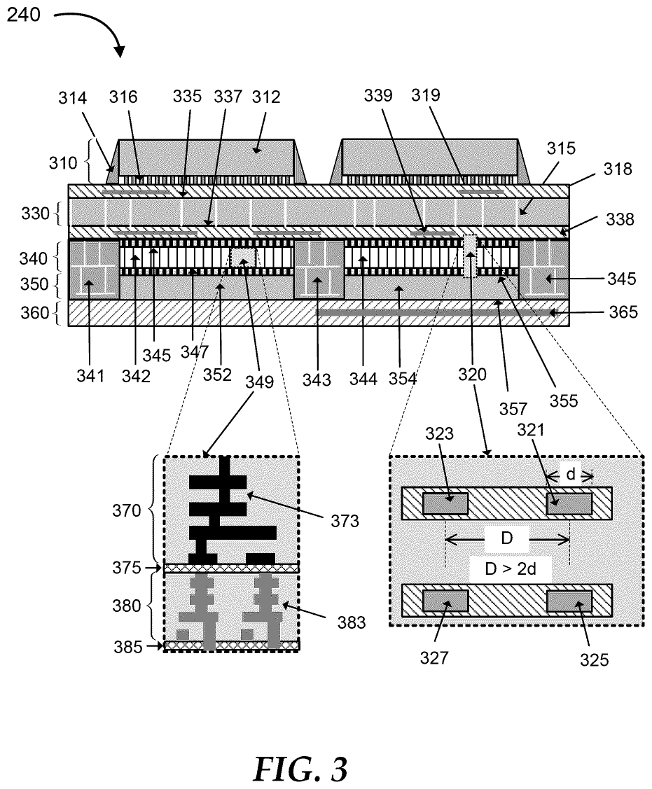

FIG. 3 is a diagram illustrating the section 240 of the integrated wafer-level circuit 190 shown in FIG. 2 according to an embodiment. The section 240 includes a power layer 310, a wafer-level interposer 330, a first layer 340, a second layer 350, and a thermal layer 360. The section 240 may include more or less than the above elements.

The wafer-level interposer 330 is a physical interface layer that electrically connects dies from different layers and other components. It may be made of silicon, glass, or organic and provides routing for signals and/or power distribution. In one embodiment, the wafer-level interposer 330 is made of silicon. It has through-silicon vias (TSVs) 315 to provide interconnects to other layers. The TSVs 315 are vertical electrical connections that connect stacked components in three-dimensional (3D) ICs. In one embodiment, the TSVs 315 TSVs are made by etching trenches into silicon and then filling them with insulating liners and metal wires. The wafer-level interposer 330 has a top interposer surface 335 and a bottom interposer surface 335. It may be bonded with a top dielectric layer 318 and a bottom dielectric layer 338.

The power layer 310 is disposed on the top interposer surface 335 through the top dielectric layer 318. The power layer 310 is a layer that has a main function of providing power regulation. It includes M voltage regulator modules (VRMs) 312. For illustrative purposes, two VRMs 312 are shown. The VRMs 132 are attached to the top dielectric layer 318 by solder joints 316. Underfill 314 may be used to protect the solder joints 316 from mechanical and reliability failures. The VRMs 132 provide a source of constant voltages to various components in the circuit. The top dielectric layer 310 may include integrated stack capacitors (ISCs) 319. The ISCs 319 provide decoupling and filtering to suppress power noise from the VRMs 312. In one embodiment, the ISC 319 includes multi-layers of conductive material stacked vertically to achieve a high-capacitance density in a small area. It may be a vertical cylinder array having many capacitive vias. It may effectively suppress high-frequency power noise.

The first layer 340 is attached to the bottom interposer surface 335 at the bottom dielectric layer 338. The bottom dielectric layer 338 may include ISCs 339 which provide decoupling and filtering to suppress various noise sources in the circuit. The first layer 340 has a top first surface 345 and a bottom first surface 347. The top first surface 345 is bonded to the bottom dielectric layer 338 so that it is attached to the bottom interposer surface 335. It includes N first-layer dies having first-layer integrated circuits (ICs) where N is a positive integer. For illustrative purposes, two dies 342 and 344 are shown. The two dies 342 and 344 may contain various types of ICs such as applications specific integrated circuits (ASICs), memories, and input/output (IO) processors. They are separated by dielectric layers 341, 343, and 345. These dielectric layers have vias to provide interconnects. The dies 342 and/or 344 may have sections 320 and 347.

Section 320 illustrates a design rule for the pads 321, 323, 325, and 327. The pads 321 323, 325, and 327 are designated areas or metal plates that provide electrical contacts between the components and layers. As shown in FIG. 3, pads 321 and 323 are located on the top surface of the first layer 340. Pads 325 and 327 are located on the bottom surface of the first layer 340 in positions corresponding to pads 321 and 323, respectively. The pads 321, 323, 325, and 327 are the same size and are made of metal such as copper (Cu). The diameter of the pads 321, 323, 325, and 327 is d. The distance or pitch between adjacent pads on the same surface is D. D is measured as the distance between the centers of two adjacent pads. The design rule is that the pitch D of adjacent metal pads is greater than a short-circuit distance based on, or related to, a diameter of the metal pads. This short circuit distance is defined as two times d:

$$D > 2 d \qquad ( 1 )$$

The design rule is to prevent Cu—Cu short failures due to short circuits, which may occur due to the redundant design to mitigate the defective Cu interconnects. The Cu—Cu short failures may lead to electric over stress (EOS) damage. The EOS damage is thermal damage resulting from an event when a current or voltage exceeds specification limits of a circuit.

Section 347 illustrates the embedding of a BSPDN. Section 347 shows layers 370 and 380. The layer 370 includes vias 373 for power delivery as part of a BSPDN. The layer 380 is on a dielectric layer 385 and includes vias 383 for signal layers and interconnects. The two layers are separated by a layer 375 which may be a transistor layer.

The second layer 350 is attached to, or bonded on, the first layer 340. It has a top second surface 355 and a bottom second surface 357. The top second surface 355 is attached to, or bonded on, ‘the bottom first surface 347 such that the two surfaces may form a single surface. The second layer 350 includes P second-layer dies having second-layer ICs where P is a positive integer. For illustrative purposes, two dies 352 and 354 are shown. The two dies 352 and 354 may contain various types of ICs such as ASICs, memories, IO processors, and interface circuits (e.g., communication interface). They are separated by dielectric layers 341, 343, and 345.

The wafer-level thermal layer 360 provides thermal management to the system. It may have an embedded cooling network 365 of liquid cooling channels. It is bonded on, attached to, or connected to the second layer 350 at the bottom second surface 357. The thermal layer 360 provides efficient thermal management without using any thermal interface materials (TIMs).

The direct integration of the VRMs 312 on the wafer-level interposer 350, the embedding of ISCs 339 in the interposer 350, and the BSPDN in dies 342 and/or 344 may significantly improve the power delivery network (PDN) performance of the integrated wafer or wafer-level circuit 190. The integration of the ICs with BSPDN in dies 342 and/or 344 and the ICs to the wafer-level interposer 350 is gapless, i.e., having no gaps, with much better thermal dissipation. This is achieved by the Die-on-Wafer (DoW) hybrid bonding technique with dielectric layers filled in the inter-die gaps. The wafer-level thermal layer 360 may be a diamond wafer of a Si (or glass) wafer with embedded liquid channels bonded to the memory stacks using Wafer on Wafer (WoW) fusion bonding or other techniques for superior thermal management.

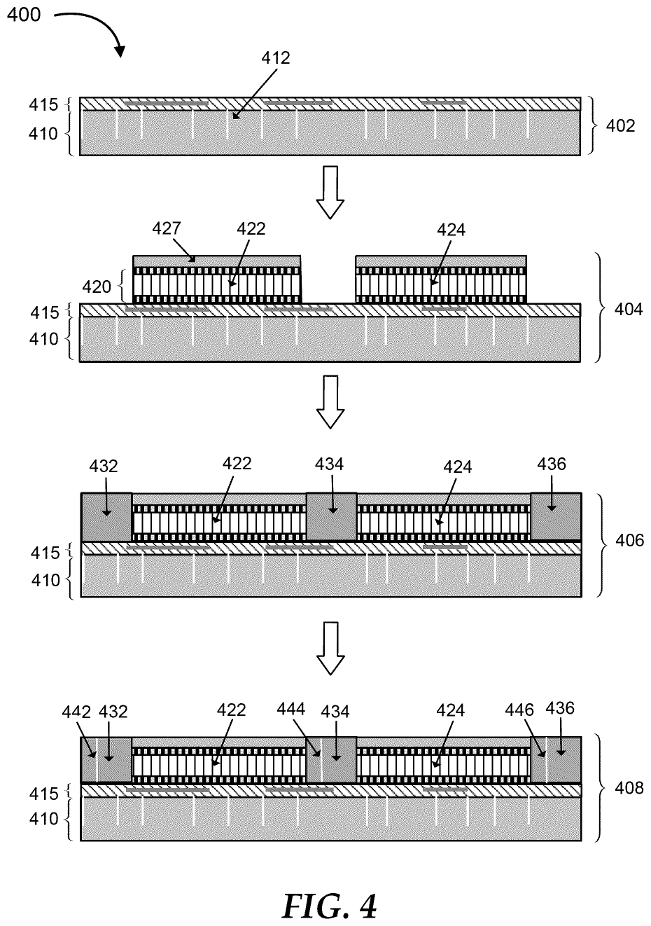

FIG. 4 is a diagram illustrating the first four stages of a manufacturing process 400 of the integrated wafer-level circuit 190 according to an embodiment. The process 400 is efficient, produces highly integrated wafer-level circuit, and provides higher yield and lower cost compared with other techniques. Instead of yielding the entire wafer with advanced silicon node, good small dies may be picked and integrated on a wafer-level interposer produced by a matured silicon process. The first four stages of a manufacturing process 400 produce devices or packages 402, 404, 406, and 408 at the first, second, third, and fourth stages, respectively, of the process. For illustrative purposes, only a section having two dies similar to the section 240 in FIG. 2 are shown. ;

At the first stage, the wafer 402 includes a wafer-level interposer 410 and a layer 415. The wafer-level interposer 410 is at full thickness and includes TSVs 412. The layer 415 includes ISCs. At the second stage, the process 400 bonds a first layer 420 on the layer 415 using a Die-on-Wafer (DoW) bonding technique. A dielectric layer 427 is bonded on the first layer 420. The first layer 420 has two circuits 422 and 424 which may be any types of ICs including ASICs and memory circuits. The result is the package 404.

At the third stage, the process 400 attaches dielectric layers 432, 434, and 436 to fill the gaps between the circuits 422 and 424. The dielectric layers 432, 434, and 436 may be formed by plasma-enhanced chemical vapor deposition (PECVD) or other techniques. The result is the package 406. At the fourth stage, the package 408 is formed. If needed, the process 400 forms vias 442, 444, and 446 in the dielectric layers 432, 434, and 436, respectively.

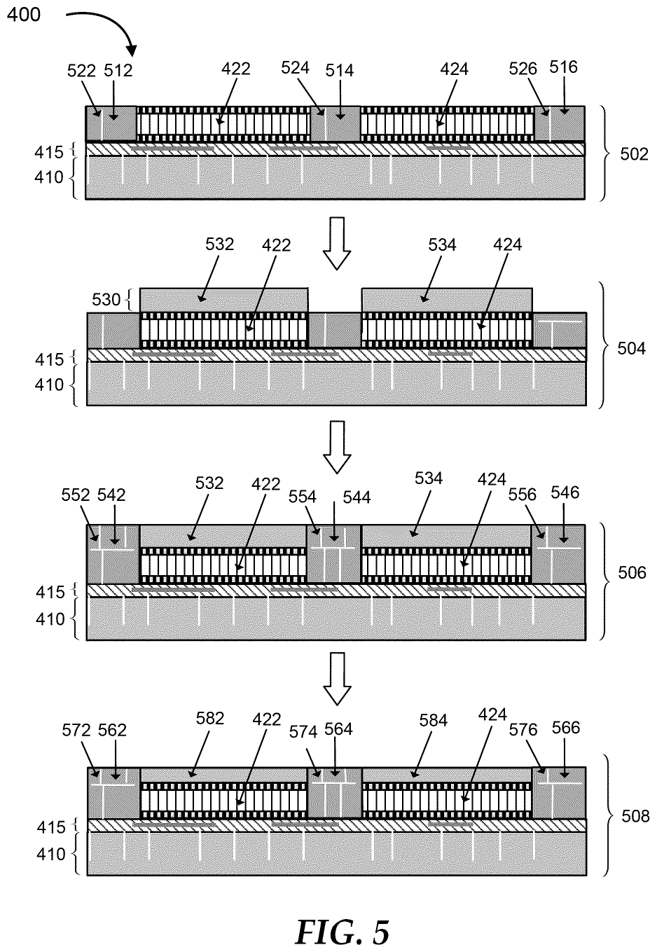

FIG. 5 is a diagram illustrating the second four stages of the manufacturing process 400 of the integrated wafer-level circuit 190 according to an embodiment. The second four stages of a manufacturing process 400 produce devices or packages 502, 504, 506, and 508 at the fifth, sixth, seventh, and eighth stages, respectively, of the process.

At the fifth stage, the process 400 thins the dielectric layers 432, 434, and 436 to produce the thinned dielectric layers 512, 514, and 516 having vias 522, 524, and 526, respectively. The process 400 may involve thinning down, polishing, through dielectric layer via formation, Cu barrier and seed layer deposition, and Cu filling steps. The result is the package 502. At the sixth stage, the process 400 forms a second layer 530 by bonding dies 532 and 534 on the dies 422 and 424, respectively using die-on-wafer (DoW) bonding technique. The dies 532 and 534 may include any types of ICs such as ASICs, memories, and IO circuits. The result is the package 504.

At the seventh stage, the process 400 fills the inter-die gaps by dielectric layers 542, 544, and 546 which include TSVs 552, 554, and 556, respectively. The result is the package 506. At the eighth stage, the process 400 thins down the dielectric layers and the second layer 530 to produce the dielectric layers 562, 564, and 566 having TSVs 572, 574, and 576, respectively. The result is the package 508.

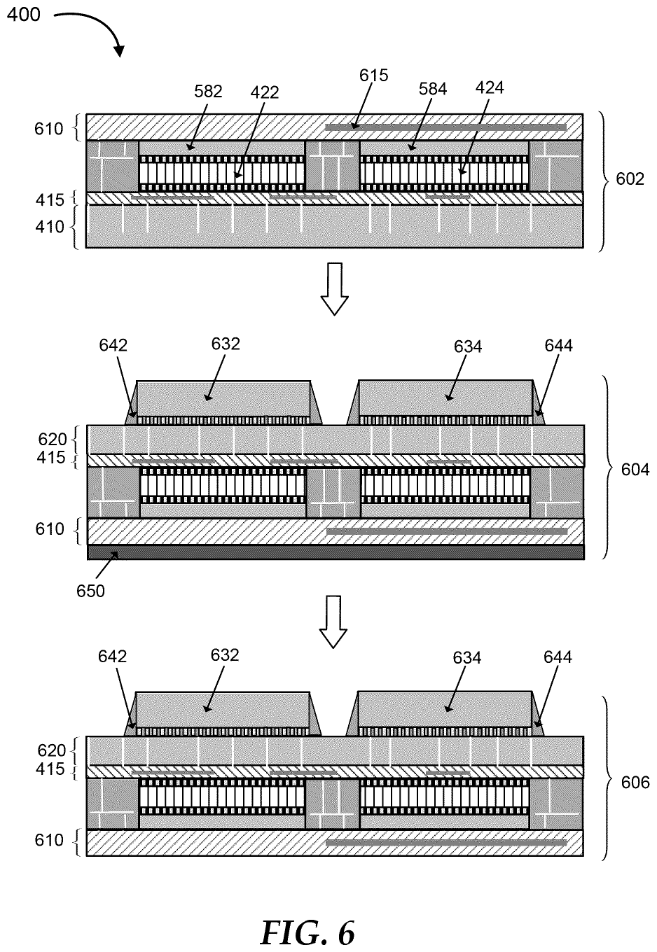

FIG. 6 is a diagram illustrating the last three stages of the manufacturing process 400 of the integrated wafer-level circuit 190 according to an embodiment. The last three stages of the manufacturing process 400 produce devices or packages 602, 604, and 606 at the ninth, tenth, and eleventh stages, respectively, of the process.

At the ninth stage, the process 400 bonds a thermal layer 610 on top of the second layer 530 which now includes dies 582 and 584. The thermal layer 610 may be formed by attaching or bonding a diamond wafer to the dies 582 and 584 using a wafer-on-wafer (WoW) fusion bonding technique or any kind of silicon-diamond bonding technique. Instead of diamond wafer, a silicon or glass wafer with embedded liquid cooling channels may be bonded to dies 582 and 584 using WoW fusion bonding, or any other Si—Si, Si—SiO₂ bonding technique. The result is the package 602.

At the tenth stage, the process 400 thins down the interposer layer 410 to produce a thinned interposer 620 which exposes the TSVs. A glass carrier 650 may be attached or bonded to the diamond or Si/glass lids for better mechanical support during interposer thinning and VRM assembly process. Bumps are then formed on the interposer 620. VRMs 632 and 634 are then attached to the interposer 620 using either Chip-on-Wafer (CoW) thermal compression bonding (TCB) or wafer-level solder mask reflow process, or any other techniques. Underfill 642 and 644 may be used to help prevent mechanical damage or improve reliability performance of solder joints. The underfill may be applied by using non-conductive film (NCF) during the TCB process. Alternatively, epoxy-flux material may be applied to the solder bump before the wafer-level solder mass reflow process to have underfill around solder bumps. The result is the package 604.

At the eleventh stage, the process 400 removes, detaches, or debonds the carrier from the thermal layer 610. The final result is the integrated package 606.

The scheme to integrate various types of circuits or components into a wafer is flexible to accommodate several alternatives. The following alternatives are illustrative examples of alternative embodiments. Other embodiments may use any combination of the following embodiments.

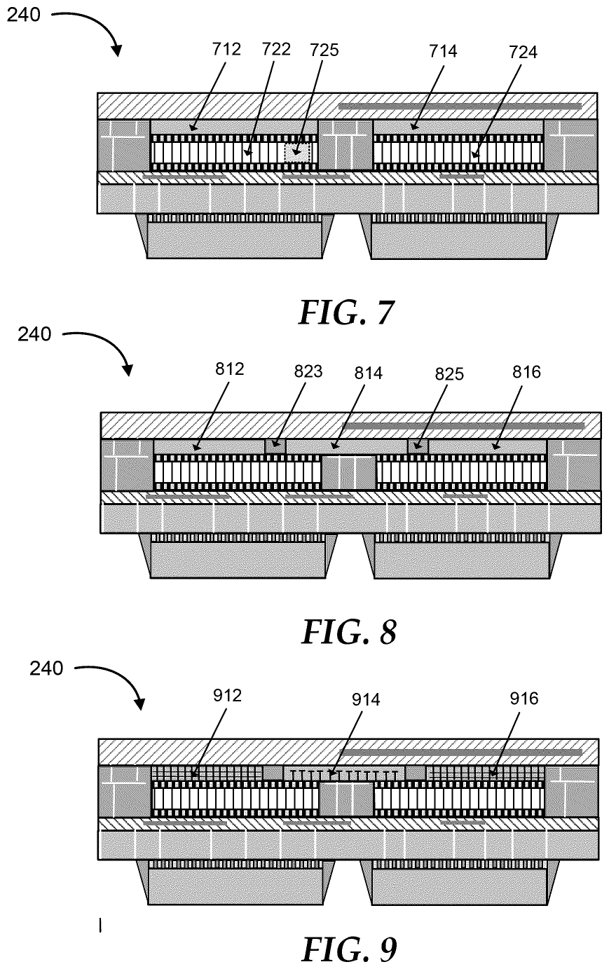

FIG. 7 is a diagram illustrating an integrated wafer-level circuit 240 having ASICs with and without BSPDN according to an embodiment. The integrated wafer-level circuit 240 includes first-layer dies 722 and 724 and second-layer dies 712 and 714. The first-layer die 722 may include a BSPDN 725 while the first-layer die 724 does not have any BSPDN.

FIG. 8 is a diagram illustrating an integrated wafer-level circuit 240 having a mix of ICs in the layers according to an embodiment. The integrated wafer-level circuit 240 includes second-layer dies 812, 814, and 816 separated by dielectric layers 823 and 825. Each of the second-layer dies 812, 814, and 816 may have a size or dimensions that are different from the dies in the first layer by a predetermined threshold. This predetermined threshold depends on the number of dies on the first layer and the number of dies on the second layer. In one embodiment, the first layer and the second layer have sizes or dimensions that are approximately the same. Therefore, suppose a layer is divided into dies of equal proportions, if the number of the first-layer dies is different than the number of the second-layer dies, then each first-layer die will have a size different from each second-layer die.

FIG. 9 is a diagram illustrating an integrated wafer-level circuit 240 having a mix of memory stacks in the layers according to an embodiment. The ICs in the second-layer dies 912, 914, and 916 may be any combination of circuits including three-dimensional (3D) IC stacks such as customized memory die stacks, ASIC-to-IO, and ASIC-to-ASIC stacks. They may be formed as individual die stacks and then bonded to the first layer dies.

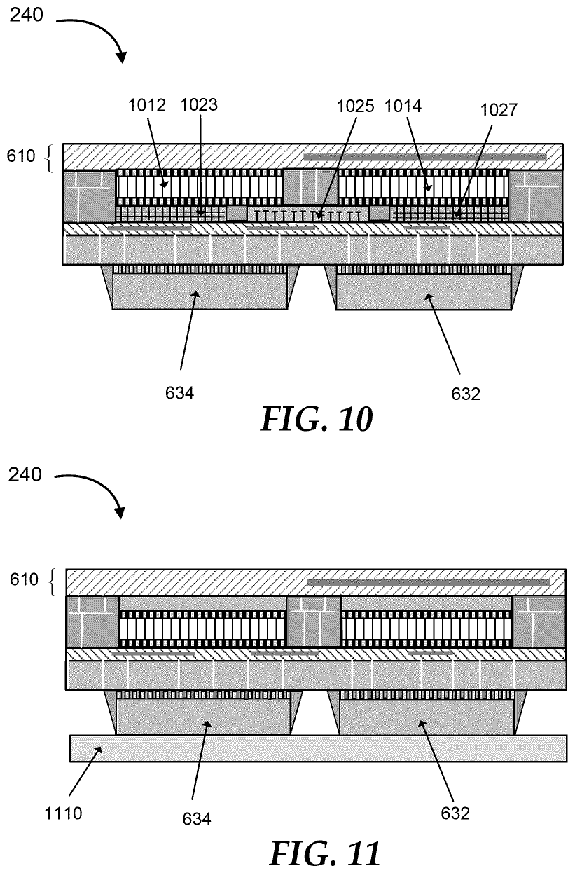

FIG. 10 is a diagram illustrating an integrated wafer-level circuit 240 having the layer circuits re-arranged in the layers according to an embodiment. The integrated wafer-level circuit 240 may have dies 1012 and 1014 containing ASICs to be close to the thermal layer 610. Since ASICs typically generate more heat than memory circuits, it may be more efficient to place ASICs close to the thermal layer. Heat generated from the high-power ASIC dies may quickly dissipate through the adjacent diamond or Si/glass lid with embedded liquid channels. Dies 1023, 1025, and 1027 may contain memory circuits, IO processors, interface circuits, or even other ASICs.

FIG. 11 is a diagram illustrating an integrated wafer-level circuit 240 having a heat sink or lid according to an embodiment. The integrated wafer-level circuit 240 includes a heat sink or lid 1110 attached to the top surface of the VRMs 632 and 634. Together with the thermal layer 610, the heat sink 1110 provides even better thermal dissipation.

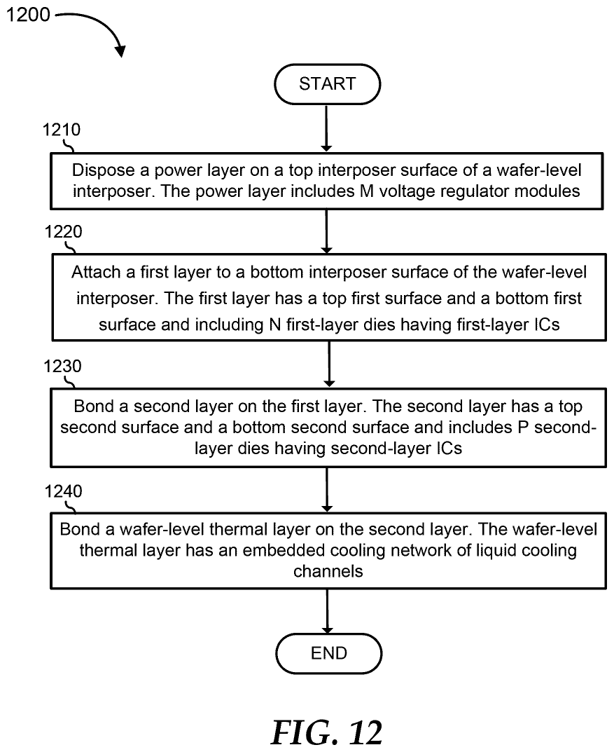

FIG. 12 is a flow chart illustrating a process 1200 of manufacturing an integrated wafer-level circuit according to an embodiment.

Upon START, the process 1200 disposes a power layer on a top interposer surface of a wafer-level interposer (Block 1210). The power layer includes M voltage regulator modules where M is a positive integer. The wafer-level interposer includes integrated stack capacitors and through-silicon vias.

Next, the process 1200 attaches a first layer to a bottom interposer surface of the wafer-level interposer (Block 1220). The first layer has a top first surface and a bottom first surface. It includes N first-layer dies having first-layer integrated circuits (ICs). N is a positive integer.

Then, the process 1200 attaches a second layer to, or bonds a second layer on, the first layer (Block 1230). The second layer has a top second surface and a bottom second surface. It includes P second-layer dies having second-layer ICs. P is a positive integer. One of the N first-layer dies and the P second-layer dies has metal pads each having a diameter d. A pitch D of adjacent metal pads is greater than two times d. In one embodiment, at least one of the first layer or the second layer includes homogeneous integrated circuits. For example, all the first-layer ICs may be ASICs and all the second-layer ICs may be memories. In another embodiment, at least one of the first layer or the second layer includes heterogeneous integrated circuits. For example, the first-layer ICs may include a mix of memory circuits and IO circuits while the second-layer ICs may include ASICs only. In one embodiment, at least one of the N first-layer dies has a size different from at least one of the P second-layer dies. In addition, one of the N first-layer dies or the P second-layer dies has an integrated circuit with backside power delivery network.

Next, the process 1200 attaches a wafer-level thermal layer to, or bonds a wafer-level thermal layer on, the second layer (Block 1240). The wafer-level thermal layer has an embedded cooling network of liquid cooling channels. The wafer-level thermal layer is made of one of diamond, glass, or silicon. The process is then terminated.

Embodiments of the subject matter and the operations described in this specification may be implemented in digital electronic circuitry, or in computer software, firmware, or hardware, including the structures disclosed in this specification and their structural equivalents, or in combinations of one or more of them. Embodiments of the subject matter described in this specification may be implemented as one or more computer programs, i.e., one or more modules of computer-program instructions, encoded on computer-storage medium for execution by, or to control the operation of data-processing apparatus. Alternatively or additionally, the program instructions can be encoded on an artificially-generated propagated signal, e.g., a machine-generated electrical, optical, or electromagnetic signal, which is generated to encode information for transmission to suitable receiver apparatus for execution by a data processing apparatus. A computer-storage medium can be, or be included in, a computer-readable storage device, a computer-readable storage substrate, a random or serial-access memory array or device, or a combination thereof. Moreover, while a computer-storage medium is not a propagated signal, a computer-storage medium may be a source or destination of computer-program instructions encoded in an artificially-generated propagated signal. The computer-storage medium can also be, or be included in, one or more separate physical components or media (e.g., multiple CDs, disks, or other storage devices). Additionally, the operations described in this specification may be implemented as operations performed by a data-processing apparatus on data stored on one or more computer-readable storage devices or received from other sources.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable sub-combination. Moreover, although features may be described above as acting in certain combinations and even initially claimed as such, one or more features from a claimed combination may in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims.

What is claimed is:

1. A device comprising:
a wafer-level interposer having a top interposer surface and a bottom interposer surface;
a power layer disposed on the top interposer surface, the power layer including at least one voltage regulator module;
a first layer attached to the bottom interposer surface, the first layer including at least one first-layer die having at least one first-layer integrated circuit (IC);
a second layer bonded on the first layer, the second layer including at least one second-layer die having at least one second-layer IC; and
a wafer-level thermal layer having an embedded cooling network of at least one liquid cooling channel and attached to the second layer.

2. The device of claim 1,
wherein a pitch of adjacent first metal pad and second metal pad is greater than a short-circuit distance based on a diameter of one of the first metal pad or a second metal pad.

3. The device of claim 1, wherein the wafer-level interposer includes at least one vertically stacked capacitor.

4. The device of claim 1, wherein the wafer-level interposer includes at least one through-silicon via for an electrical interconnection.

5. The device of claim 1, wherein at least one of the first layer or the second layer includes at least a first IC having a same type as a second IC in one of the at least one first-layer ICor the at least one second-layer IC.

6. The device of claim 1, wherein at least one of the first layer or the second layers includes at least a first IC having a different type from a second IC in one of the at least one first-layer IC or the at least one second-layer IC.

7. The device of claim 1, wherein the wafer-level thermal layer comprises at least one of diamond, glass, or silicon.

8. The device of claim 1, wherein one of the at least one first-layer IC or the at least one second-layer IC comprises an integrated circuit with backside power delivery network.

9. The device of claim 1, wherein one of the at least one first-layer IC or the at least one second-layer IC comprises one of an applications specific integrated circuit, a memory circuit, or an interface circuit.

10. The device of claim 1, wherein the at least one first-layer die has a size different from the at least one second-layer die by a predetermined threshold.

11. A method comprising:
disposing a power layer on a top interposer surface of a wafer-level interposer, the power layer including at least one voltage regulator module;
attaching a first layer to a bottom interposer surface of the wafer-level interposer, the first including at least one first-layer die having at least one first-layer integrated circuits (IC);
attaching a second layer to the first layer, the second layer including at least one second-layer die having at least one second-layer IC; and
attaching a wafer-level thermal layer to the second layer, the wafer-level thermal layer having an embedded cooling network of at least one liquid cooling channel.

12. The method of claim 11,
wherein a pitch of adjacent first metal pad and second metal pad is greater than a short-circuit distance based on a diameter of one of the first metal pad or a second metal pad.

13. The method of claim 11, wherein the wafer-level interposer includes at least one vertically stacked capacitor.

14. The method of claim 11, wherein the wafer-level interposer includes at least one through-silicon via for an electrical interconnection.

15. The method of claim 11, wherein at least one of the first layer or the second layer includes at least a first IC having a same type as a second IC in one of the at least one first-layer IC or the at least one second-layer IC.

16. The method of claim 11, wherein at least one of the first layer or the second layers includes at least a first IC having a different type from a second IC in one of the at least one first-layer IC or the at least one second-layer IC.

17. The method of claim 11, wherein the wafer-level thermal layer comprises at least one of glass or silicon.

18. The method of claim 11, wherein one of the at least one first-layer die or the at least one second-layer die comprises an integrated circuit with backside power delivery network.

19. A system comprising:
a wafer package comprising:
a wafer-level interposer having a top interposer surface and a bottom interposer surface;
a power layer disposed on the top interposer surface, the power layer including a first number of voltage regulator modules;
a first layer attached to the bottom interposer surface, the first layer including a second number of first-layer dies having first-layer integrated circuits (ICs);
a second layer attached to the first layer, the second layer including a third number of second-layer dies having second-layer ICs; and
a wafer-level thermal layer having an embedded cooling network of liquid cooling channels and attached to the second layer,
wherein M, N, and P are positive integers.

20. The system of claim 19,
wherein a pitch of adjacent first metal pad and second metal pad is greater than a short-circuit distance based on a diameter of the first metal pad or a second metal pad.
